(19) United States
(12) Patent Application Publication
(10) Pub. No.: US 2026/0142434 A1
(43) Pub. Date: May 21, 2026

(54) LASER APPARATUS AND METHOD OF MANUFACTURING ELECTRONIC DEVICE

(71) Applicant: Gigaphoton Inc., Tochigi (JP)

(72) Inventor: Yousuke FUJIMAKI, Tochigi (JP)

(73) Assignee: Gigaphoton Inc., Tochigi (JP)

(21) Appl. No.: 19/441,808

(22) Filed: Jan. 6, 2026

Related U.S. Application Data
(63) Continuation of application No. PCT/JP2023/030934, filed on Aug. 28, 2023.

(51) Int. Cl. H01S 3/00; G03F 7/20; H01S 3/03

(52) U.S. Cl. CPC H01S 3/0057; H01S 3/03; G03F 7/2006

(57) ABSTRACT

A laser apparatus includes a laser oscillator including an optical resonator and a pair of electrodes that apply a voltage to a laser gas to cause discharge, and configured to output a first pulse laser beam, a first optical pulse stretcher configured to output a second pulse laser beam for which a pulse time width of the first pulse laser beam is extended by transmitting a part of the first pulse laser beam, making the other part circulate once, and outputting first transmitted light and first once-circulating light that spatially partially overlap with a first shift amount, and a second optical pulse stretcher configured to output a third pulse laser beam for which a pulse time width of the second pulse laser beam is extended by transmitting a part of the second pulse laser beam, making the other part circulate once, and outputting second transmitted light and second once-circulating light that spatially partially overlap with a second shift amount, which is different from the first shift amount.

### CROSS-REFERENCE TO RELATED APPLICATIONS

The present application is a continuation application of International Application No. PCT/JP2023/030934, filed on Aug. 28, 2023, the entire contents of which are hereby incorporated by reference.

### BACKGROUND

### 1. Technical Field

The present disclosure relates to a laser apparatus and a method of manufacturing an electronic device.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser apparatus for exposure, a KrF excimer laser apparatus that outputs a laser beam having a wavelength of about 248 nm and an ArF excimer laser apparatus that outputs a laser beam having a wavelength of about 193 nm are used.

Spectral linewidths of spontaneous oscillation beams of the KrF excimer laser apparatus and the ArF excimer laser apparatus are as wide as from 350 pm to 400 pm. Therefore, when a projection lens is formed of a material that transmits ultraviolet light such as KrF and ArF laser beams, chromatic aberration may occur. As a result, the resolution may decrease. Thus, the spectral linewidth of the laser beam output from the gas laser apparatus needs to be narrowed to an extent that the chromatic aberration is ignorable. Therefore, in a laser resonator of the gas laser apparatus, a line narrowing module (LNM) including a line narrowing element (such as etalon or grating) may be provided in order to narrow the spectral linewidth. Hereinafter, a gas laser apparatus with a narrowed spectral linewidth is referred to as a line narrowing gas laser apparatus.

### LIST OF DOCUMENTS

### Patent Documents

Patent Document 1: U.S. Patent Application Publication No. 2008/0144671

### SUMMARY

A laser apparatus according to one aspect of the present disclosure includes a laser oscillator, a first optical pulse stretcher, and a second optical pulse stretcher. The laser oscillator includes an optical resonator and a pair of electrodes that apply a voltage to a laser gas to cause discharge, and is configured to output a first pulse laser beam. The first optical pulse stretcher is disposed in an optical path of the first pulse laser beam, is configured to output a second pulse laser beam for which a pulse time width of the first pulse laser beam is extended by transmitting a part of the first pulse laser beam, making the other part circulate once, and outputting first transmitted light and first once-circulating light, and is configured such that an optical path of the first transmitted light and an optical path of the first once-circulating light spatially partially overlap with a first shift amount in a first direction. The second optical pulse stretcher is disposed in an optical path of the second pulse laser beam, is configured to output a third pulse laser beam for which a pulse time width of the second pulse laser beam is extended by transmitting a part of the second pulse laser beam, making the other part circulate once, and outputting second transmitted light and second once-circulating light, and is configured such that an optical path of the second transmitted light and an optical path of the second once-circulating light spatially partially overlap with a second shift amount, which is different from the first shift amount, in the first direction.

A method of manufacturing an electronic device according to one aspect of the present disclosure includes generating a laser beam with a laser apparatus, outputting the laser beam to an exposure apparatus, and exposing a photosensitive substrate to the laser beam within the exposure apparatus to manufacture an electronic device. The laser apparatus includes a laser oscillator including an optical resonator and a pair of electrodes that apply a voltage to a laser gas to cause discharge, and configured to output a first pulse laser beam, a first optical pulse stretcher disposed in an optical path of the first pulse laser beam, configured to output a second pulse laser beam for which a pulse time width of the first pulse laser beam is extended by transmitting a part of the first pulse laser beam, making the other part circulate once, and outputting first transmitted light and first once-circulating light, and configured such that an optical path of the first transmitted light and an optical path of the first once-circulating light spatially partially overlap with a first shift amount in a first direction, and a second optical pulse stretcher disposed in an optical path of the second pulse laser beam, configured to output a third pulse laser beam for which a pulse time width of the second pulse laser beam is extended by transmitting a part of the second pulse laser beam, making the other part circulate once, and outputting second transmitted light and second once-circulating light, and configured such that an optical path of the second transmitted light and an optical path of the second once-circulating light spatially partially overlap with a second shift amount, which is different from the first shift amount, in the first direction.

### BRIEF DESCRIPTION OF THE DRAWINGS

Some embodiments of the present disclosure will be described below, by way of example only, with reference to the accompanying drawings.

FIG. 1 schematically illustrates a configuration of an exposure system in a comparative example.

FIG. 2 schematically illustrates the configuration of the exposure system in the comparative example.

FIG. 3 schematically illustrates an example of an optical pulse stretcher that shifts a traveling direction of circulating light in a V direction.

FIG. 4 illustrates a pulse time waveform of a fourth pulse laser beam entering the optical pulse stretcher illustrated in FIG. 3.

FIG. 5 illustrates a pulse time waveform of a fifth pulse laser beam output from the optical pulse stretcher illustrated in FIG. 3.

FIG. 6 schematically illustrates an example of the optical pulse stretcher that shifts the traveling direction of the circulating light in an H direction.

FIG. 7 illustrates a beam cross-sectional shape of a second pulse laser beam output from the optical pulse stretcher illustrated in FIG. 6.

FIG. 8 illustrates an example of an optical path shift by first and second optical pulse stretchers.

FIG. 9 illustrates another example of the optical path shift by the first and second optical pulse stretchers.

FIG. 10 illustrates a first example of the optical path shift by the first and second optical pulse stretchers in a first embodiment.

FIG. 11 illustrates a second example of the optical path shift by the first and second optical pulse stretchers in the first embodiment.

FIG. 12 illustrates an example of the optical path shift by first to third optical pulse stretchers in the first embodiment.

FIG. 13 illustrates an example of the optical path shift by first to fourth optical pulse stretchers in the first embodiment.

FIG. 14 is a graph illustrating a result of simulating a relationship between an optical path shift amount due to one circulation in the optical pulse stretcher and a correlation of speckle patterns of transmitted light and once-circulating light.

FIG. 15 illustrates an example of the optical path shift by the first to fourth optical pulse stretchers in a second embodiment.

FIG. 16 schematically illustrates an example of the optical pulse stretcher included in a third embodiment.

FIG. 17 illustrates an example of the optical path shift by the first to fourth optical pulse stretchers in the third embodiment.

FIG. 18 is a graph illustrating a result of simulating the relationship between the optical path shift amount due to one circulation in the optical pulse stretcher and the correlation of the speckle patterns of the transmitted light and the once-circulating light.

FIG. 19 schematically illustrates a first modification of the optical pulse stretcher.

FIG. 20 schematically illustrates a second modification of the optical pulse stretcher.

### DESCRIPTION OF EMBODIMENTS

### Contents

1. Comparative Example
   1.1 Exposure System
   1.2 Exposure Apparatus 200
      1.2.1 Configuration
      1.2.2 Operation
   1.3 Laser Apparatus 100
      1.3.1 Configuration
      1.3.2 Operation
   1.4 Speckle
   1.5 Examples of Optical Pulse Stretcher
      1.5.1 Optical Pulse Stretcher that Shifts Traveling Direction of Circulating Light in V Direction
      1.5.2 Optical Pulse Stretcher that Shifts Traveling Direction of Circulating Light in H Direction
   1.6 Problem of Comparative Example
2. Multiple Optical Pulse Stretchers with Different Absolute Values of Optical Path Shift Amount
   2.1 Principle
   2.2 First Example
   2.3 Second Example
   2.4 Third Example
   2.5 Fourth Example
   2.6 Relationship between Optical Path Shift Amount and Speckle Pattern Correlation
   2.7 Effect
3. Optical Pulse Stretcher that Shifts Optical Path in V Direction
   3.1 Configuration
   3.2 Effect
4. Optical Pulse Stretcher where Optical Path Shift Includes Shift of Light Output Position
   4.1 Configuration
   4.2 Effect
5. Others
   5.1 Modifications of Optical Pulse Stretcher
   5.2 Supplement

Hereinafter, embodiments of the present disclosure will be described in detail with reference to the drawings. The embodiments described below show some examples of the present disclosure and do not limit contents of the present disclosure. In addition, all configurations and operations described in the embodiments are not necessarily essential as configurations and operations of the present disclosure. Here, the same components are denoted by the same reference signs, and any redundant description thereof is omitted.

### 1. Comparative Example

### 1.1 Exposure System

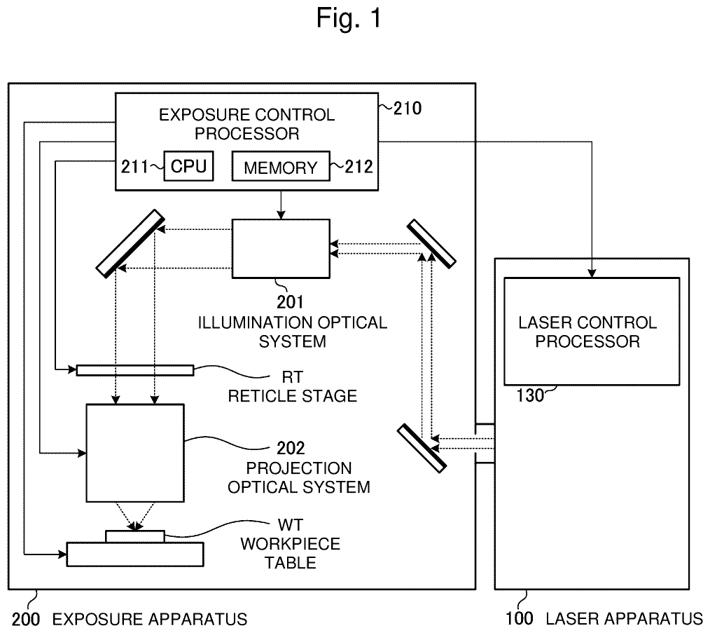

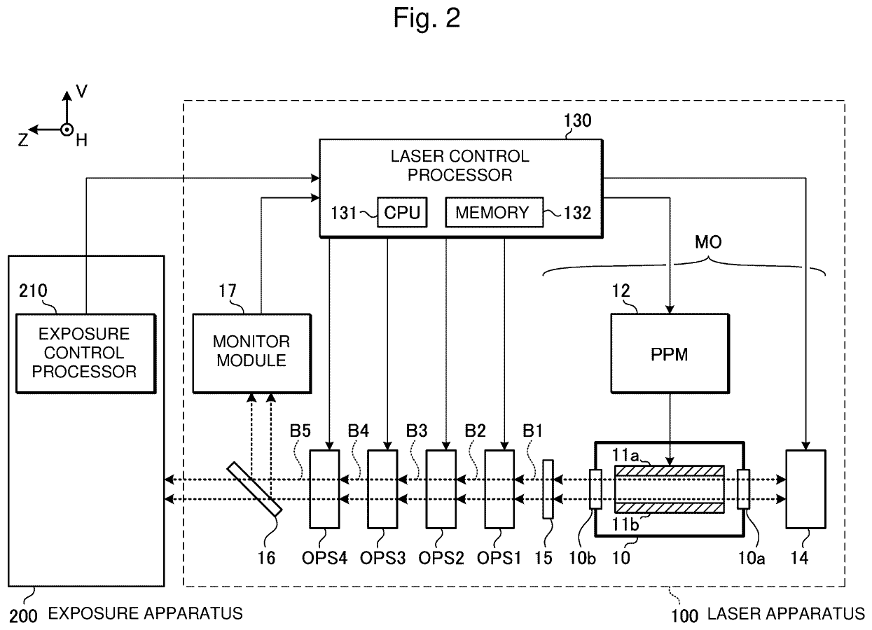

FIGS. 1 and 2 schematically illustrate a configuration of an exposure system in a comparative example. The comparative example of the present disclosure is an example recognized by the applicant as known only by the applicant, and is not a publicly known example admitted by the applicant.

The exposure system includes a laser apparatus 100 and an exposure apparatus 200. In FIG. 1, the laser apparatus 100 is illustrated in a simplified manner. In FIG. 2, the exposure apparatus 200 is illustrated in a simplified manner.

The laser apparatus 100 includes a laser control processor 130. The laser apparatus 100 is configured to output a laser beam toward the exposure apparatus 200.

### 1.2 Exposure Apparatus 200

### 1.2.1 Configuration

As illustrated in FIG. 1, the exposure apparatus 200 includes an illumination optical system 201, a projection optical system 202, and an exposure control processor 210.

The illumination optical system 201 illuminates, with a laser beam incident from the laser apparatus 100, a reticle pattern of a non-illustrated reticle disposed on a reticle stage RT.

The laser beam having transmitted through the reticle is imaged on a non-illustrated workpiece disposed on a workpiece table WT by reduced projection through the projection optical system 202. The workpiece is a photosensitive substrate such as a semiconductor wafer on which a resist film is applied.

The exposure control processor 210 is a processing device including a memory 212 in which a control program is stored and a central processing unit (CPU) 211 configured to execute the control program. The exposure control processor 210 is specifically configured or programmed to execute various kinds of processing included in the present disclosure. The exposure control processor 210 collectively controls the exposure apparatus 200 and transmits and receives various kinds of data and various signals to and from the laser control processor 130.

### 1.2.2 Operation

The exposure control processor 210 sets various parameters related to exposure conditions and controls the illumination optical system 201 and the projection optical system 202.

The exposure control processor 210 transmits data of a wavelength target value and a trigger signal to the laser control processor 130. The laser control processor 130 controls the laser apparatus 100 in accordance with those data and the signal.

The exposure control processor 210 translates the reticle stage RT and the workpiece table WT in directions opposite to each other in synchronization. Accordingly, the workpiece is exposed to the laser beam reflecting the reticle pattern.

Through such an exposure process, the reticle pattern is transferred onto the semiconductor wafer. Thereafter, an electronic device can be manufactured through a plurality of processes.

### 1.3 Laser Apparatus 100

### 1.3.1 Configuration

As illustrated in FIG. 2, the laser apparatus 100 includes, in addition to the laser control processor 130, a laser oscillator MO, first to fourth optical pulse stretchers OPS1 to OPS4, and a monitor module 17. The laser oscillator MO includes a laser chamber 10, a pulse power module (PPM) 12, a line narrowing module 14, and an output coupling mirror 15. The line narrowing module 14 and the output coupling mirror 15 constitute an optical resonator.

The laser chamber 10 is disposed in an optical path of the optical resonator. The laser chamber 10 is provided with windows 10a and 10b.

The laser chamber 10 includes a pair of electrodes 11a and 11b inside and houses laser gas containing a component of a laser medium. The laser medium is, for example, F₂, ArF, KrF, XeCl, or XeF.

A direction of an optical path axis of the optical resonator is defined as a Z direction or a −Z direction. A direction of discharge between the electrodes 11a and 11b is defined as a V direction or a −V direction. The Z direction and the V direction are perpendicular to each other, and a direction perpendicular to both is defined as an H direction or a −H direction.

The pulse power module 12 includes a non-illustrated switch and is connected to a non-illustrated charger.

The line narrowing module 14 includes a plurality of non-illustrated prisms and a non-illustrated grating. Light output from the window 10a of the laser chamber 10 is transmitted through the prisms and is incident on the grating. The grating is disposed in Littrow arrangement so that an incident angle of the light entering the grating from the prisms and a diffracting angle of diffracted light having a desired wavelength coincide. The diffracted light having the desired wavelength is transmitted through the prisms again and enters the laser chamber 10 through the window 10a. By changing a posture of at least one prism, the incident angle of the light entering the grating changes, and a wavelength selected by the line narrowing module 14 changes.

The output coupling mirror 15 is formed of a partial reflective mirror. A first optical pulse stretcher OPS1 is disposed in an optical path of a first pulse laser beam B1 output from the output coupling mirror 15. A second optical pulse stretcher OPS2 is disposed in an optical path of a second pulse laser beam B2 output from the first optical pulse stretcher OPS1. A third optical pulse stretcher OPS3 is disposed in an optical path of a third pulse laser beam B3 output from the second optical pulse stretcher OPS2. A fourth optical pulse stretcher OPS4 is disposed in an optical path of a fourth pulse laser beam B4 output from the third optical pulse stretcher OPS3.

A beam splitter 16 is disposed in an optical path of a fifth pulse laser beam B5 output from the fourth optical pulse stretcher OPS4. The beam splitter 16 transmits a part of the fifth pulse laser beam B5 with a high transmittance and reflects the other part. The fifth pulse laser beam B5 transmitted through the beam splitter 16 enters the exposure apparatus 200 as a laser beam, and the fifth pulse laser beam B5 reflected by the beam splitter 16 enters the monitor module 17.

The laser control processor 130 is a processing device including a memory 132 in which a control program is stored and a CPU 131 configured to execute the control program. The laser control processor 130 is specially configured or programmed to execute various kinds of processing included in the present disclosure.

### 1.3.2 Operation

The laser control processor 130 acquires the data of the wavelength target value from the exposure control processor 210. The laser control processor 130 transmits an initial setting signal to the line narrowing module 14 based on the wavelength target value. After output of the laser beam is started, the laser control processor 130 receives wavelength measurement data from the monitor module 17 and transmits a feedback control signal to the line narrowing module 14 based on the wavelength target value and the wavelength measurement data.

The laser control processor 130 receives the trigger signal from the exposure control processor 210. The laser control processor 130 transmits an oscillation trigger signal based on the trigger signal to the switch of the pulse power module 12.

When having received the oscillation trigger signal from the laser control processor 130, the switch is turned on. When the switch is turned on, the pulse power module 12 generates a pulsed high voltage from electric energy held in the charger. The pulse power module 12 applies the high voltage to the electrode 11a.

When the high voltage is applied to the electrode 11a, the discharge occurs between the electrodes 11a and 11b. By energy of this discharge, the laser gas in the laser chamber 10 is excited and shifts to a high energy level. When the excited laser gas then shifts to a low energy level, light having a wavelength corresponding to the energy level difference is discharged.

The light generated in the laser chamber 10 is output to an outside of the laser chamber 10 through the windows 10a and 10b. The light output from the window 10a enters the line narrowing module 14. Of the light that has entered the line narrowing module 14, light near a desired wavelength is turned back by the line narrowing module 14 and returned to the laser chamber 10.

The output coupling mirror 15 transmits and outputs a part of the light output through the window 10b and reflects the other part back to the laser chamber 10.

In this manner, the light output from the laser chamber 10 reciprocates between the line narrowing module 14 and the output coupling mirror 15. The light is amplified every time the light passes through a discharge space between the electrodes 11a and 11b. The light subjected to laser oscillation and line narrowing in this manner is output as the first pulse laser beam B1 from the output coupling mirror 15. The first to fourth optical pulse stretchers OPS1 to OPS4 extend pulse time widths of the first to fourth pulse laser beams B1 to B4 and output them as the second to fifth pulse laser beams B2 to B5, respectively. The fifth pulse laser beam B5 enters the exposure apparatus 200 as the laser beam through the beam splitter 16.

### 1.4 Speckle

A speckle is a grayscale spot generated when a laser beam is scattered at a random medium and scattered light interferes with each other. An image of this spot is called a speckle image. As an index for evaluating a speckle, a speckle contrast SC represented by a following equation is used.

$$SC = σ ( I ) / Avg ( I )$$

A standard deviation of intensity I in the speckle image is represented by σ(I), and an average value of the intensity I in the speckle image is represented by Avg(I).

The speckle acts as noise in the exposure apparatus 200, and a high speckle contrast may deteriorate an exposure performance. In order to reduce the speckle contrast, it is necessary to reduce both temporal overlap and spatial overlap of pulse laser beams. A method using an optical pulse stretcher is known to reduce both the temporal overlap and the spatial overlap of the pulse laser beams.

### 1.5 Examples of Optical Pulse Stretcher

### 1.5.1 Optical Pulse Stretcher That Shifts Traveling Direction of Circulating Light in V Direction

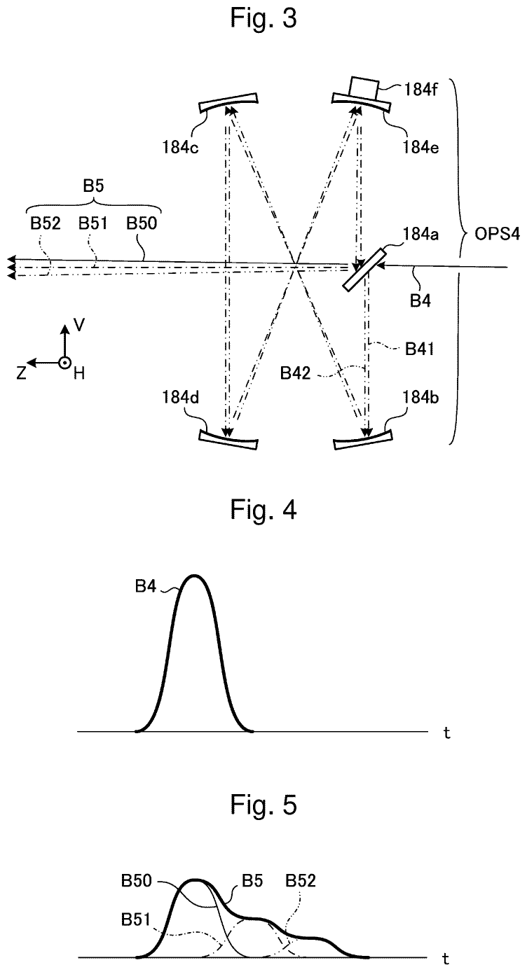

FIG. 3 schematically illustrates an example of the optical pulse stretcher that shifts a traveling direction of circulating light in the V direction. The fourth optical pulse stretcher OPS4 illustrated in FIG. 3 includes a beam splitter 184a, concave mirrors 184b to 184e, and an actuator 184f. Note that FIG. 3 is an example, and the fourth optical pulse stretcher OPS4 described with reference to FIG. 2 does not necessarily have to be as illustrated in FIG. 3, and any of the first to third optical pulse stretchers OPS1 to OPS3 may be similar to FIG. 3.

The beam splitter 184a is disposed in the optical path of the fourth pulse laser beam B4. A reflectance of the beam splitter 184a is, for example, 60%. The fourth pulse laser beam B4 is incident on a first surface of the beam splitter 184a, and the beam splitter 184a transmits a part of the fourth pulse laser beam B4 as transmitted light B50 and reflects the other part as light B41. The transmitted light B50 corresponds to fourth transmitted light to be described later. The concave mirrors 184b, 184c, 184d, and 184e are spherical mirrors and are disposed in this order in an optical path of the light B41 reflected by the beam splitter 184a. The concave mirrors 184b to 184e form a loop-shaped delay optical path. The concave mirrors 184b to 184e sequentially reflect the light B41 to make it be incident on a second surface of the beam splitter 184a.

The beam splitter 184a reflects a part of the light B41 as once-circulating light B51 and transmits the other part as light B42. The once-circulating light B51 corresponds to fourth once-circulating light to be described later. The concave mirrors 184b to 184e sequentially reflect the light B42 to make it be incident on the second surface of the beam splitter 184a.

The beam splitter 184a reflects a part of the light B42 as twice-circulating light B52.

In this way, the transmitted light B50, the once-circulating light B51, and the twice-circulating light B52 are output from the fourth optical pulse stretcher OPS4. At this time, the concave mirrors 184b to 184e are disposed so that the transmitted light B50, the once-circulating light B51, and the twice-circulating light B52 are branched as beams with their optical axes shifted in the V direction from each other. The actuator 184f may allow for fine adjustment of a V-direction shift amount of the once-circulating light B51 and the twice-circulating light B52 relative to the transmitted light B50 by changing a position or a posture of the concave mirror 184e.

FIG. 4 illustrates a pulse time waveform of the fourth pulse laser beam B4 entering the optical pulse stretcher illustrated in FIG. 3, and FIG. 5 illustrates a pulse time waveform of the fifth pulse laser beam B5 output from the optical pulse stretcher illustrated in FIG. 3. Horizontal axes in FIGS. 4 and 5 represent time t. The pulse time waveform of the fifth pulse laser beam B5 is given as a composite waveform of the pulse time waveforms of the transmitted light B50, the once-circulating light B51, and the twice-circulating light B52.

The transmitted light B50 and the once-circulating light B51 have lower peak intensity and smaller pulse energy than that of the fourth pulse laser beam B4. The twice-circulating light B52 has lower peak intensity and smaller pulse energy than that of both the transmitted light B50 and the once-circulating light B51. The other part of the light B42 may be transmitted through the beam splitter 184a and become non-illustrated three-time circulating light via the concave mirrors 184b to 184e and the beam splitter 184a, however, it has lower peak intensity and smaller pulse energy than that of the twice-circulating light B52.

The transmitted light B50, the once-circulating light B51, and the twice-circulating light B52 that are branched are overlapped at timings shifted from each other so that the temporal overlap of the pulse laser beams is reduced. In addition, the pulse time width of the fifth pulse laser beam B5 is extended compared to the fourth pulse laser beam B4.

### 1.5.2 Optical Pulse Stretcher That Shifts Traveling Direction of Circulating Light in H Direction

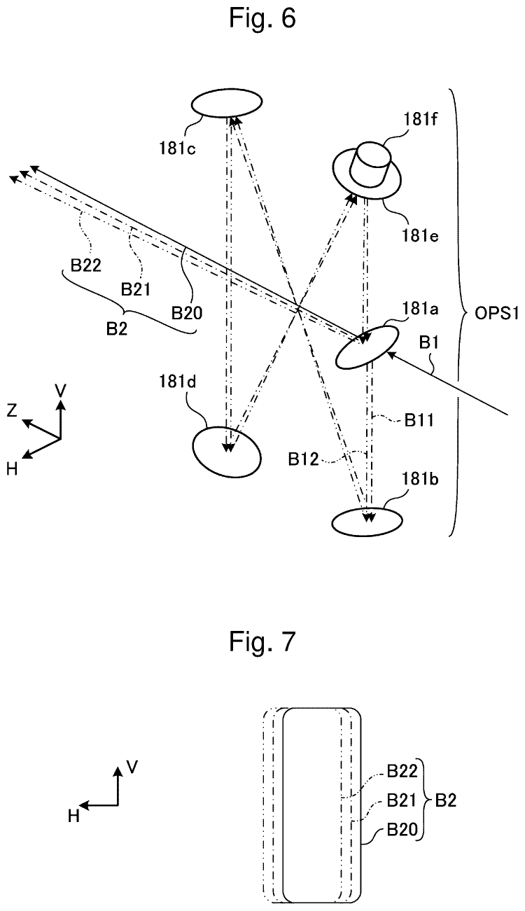

FIG. 6 schematically illustrates an example of the optical pulse stretcher that shifts the traveling direction of the circulating light in the H direction. The first optical pulse stretcher OPS1 illustrated in FIG. 6 includes a beam splitter 181a, concave mirrors 181b to 181e, and an actuator 181f. Note that FIG. 6 is an example, and the first optical pulse stretcher OPS1 described with reference to FIG. 2 does not necessarily have to be as illustrated in FIG. 6, and any of the second to fourth optical pulse stretchers OPS2 to OPS4 may be similar to FIG. 6.

The beam splitter 181a, the concave mirrors 181b to 181e, and the actuator 181f have a configuration similar to that of the beam splitter 184a, the concave mirrors 184b to 184e, and the actuator 184f described with reference to FIG. 3.

The first pulse laser beam B1 is incident on a first surface of the beam splitter 181a, and the beam splitter 181a transmits a part of the first pulse laser beam B1 as transmitted light B20 and reflects the other part as light B11. The transmitted light B20 corresponds to first transmitted light to be described later. The concave mirrors 181b to 181e sequentially reflect the light B11 to make it be incident on a second surface of the beam splitter 181a.

The beam splitter 181a reflects a part of the light B11 as once-circulating light B21 and transmits the other part as light B12. The once-circulating light B21 corresponds to first once-circulating light to be described later. The concave mirrors 181b to 181e sequentially reflect the light B12 to make it be incident on the second surface of the beam splitter 181a.

The beam splitter 181a reflects a part of the light B12 as twice-circulating light B22.

In this way, the transmitted light B20, the once-circulating light B21, and the twice-circulating light B22 are output from the first optical pulse stretcher OPS1 as the second pulse laser beam B2. At this time, the concave mirrors 181b to 181e are disposed so that the transmitted light B20, the once-circulating light B21, and the twice-circulating light B22 are branched as beams with their optical axes shifted in the H direction from each other. The actuator 181f may allow for fine adjustment of an H-direction shift amount of the once-circulating light B21 and the twice-circulating light B22 relative to the transmitted light B20 by changing a position or a posture of the concave mirror 181e.

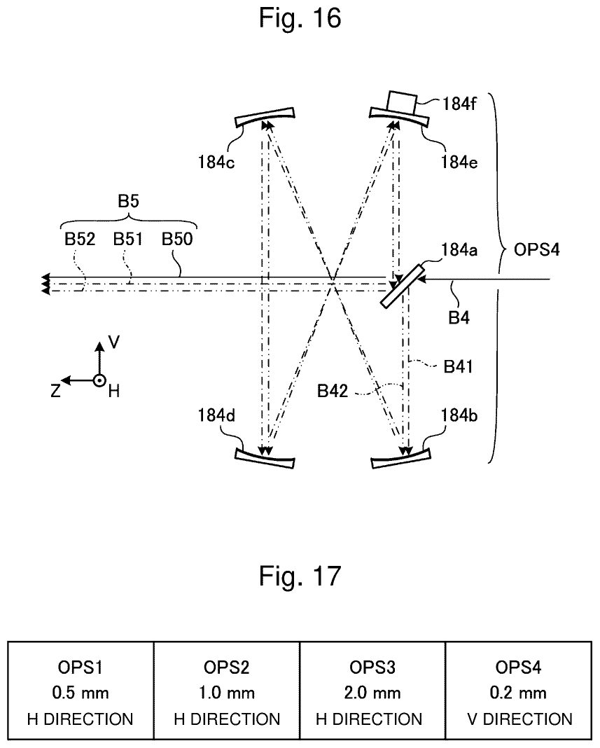

FIG. 7 illustrates a beam cross-sectional shape of the second pulse laser beam B2 output from the optical pulse stretcher illustrated in FIG. 6. The beam cross-sectional shape of the transmitted light B20 is a rectangle that is long in the V direction corresponding to a shape of the discharge space between the electrodes 11a and 11b. The concave mirrors 181b to 181e are designed so that the once-circulating light B21 and the twice-circulating light B22 also have a similar cross-sectional shape. In the second pulse laser beam B2, beam cross sections of the transmitted light B20, the once-circulating light B21, and the twice-circulating light B22 are shifted in the H direction to spatially partially overlap with each other so that the spatial overlap of the pulse laser beams is reduced. Methods for reducing the spatial overlap include a method of shifting the traveling direction of the circulating light as illustrated in FIG. 6, and a method of shifting an output position of the circulating light as described later with reference to FIG. 16.

For the pulse time waveform of the first pulse laser beam B1 and the pulse time waveform of the second pulse laser beam B2, illustrations are omitted. The point that the transmitted light B20, the once-circulating light B21, and the twice-circulating light B22 that are branched are overlapped at timings shifted from each other so that the temporal overlap of the pulse laser beams is reduced is similar to content described with reference to FIGS. 4 and 5.

In addition, the point that the beam cross sections of the transmitted light B50, the once-circulating light B51, and the twice-circulating light B52 are shifted to spatially partially overlap with each other in the fourth optical pulse stretcher OPS4 illustrated in FIG. 3 so that the spatial overlap of the pulse laser beams is reduced is similar to the content described with reference to FIG. 7, but is different in that the beam cross sections are shifted in the V direction in FIG. 3.

### 1.6 Problem of Comparative Example

As described above, by using the optical pulse stretcher to reduce both the temporal overlap and the spatial overlap of the pulse laser beams, the speckle contrast can be reduced. However, when a plurality of optical pulse stretchers are disposed in the optical path of the pulse laser beam, it is not known how the transmitted light and the circulating light should be shifted in each optical pulse stretcher to efficiently reduce the speckle contrast. The embodiments described in the present disclosure relate to efficient reduction of the speckle contrast using optical pulse stretchers.

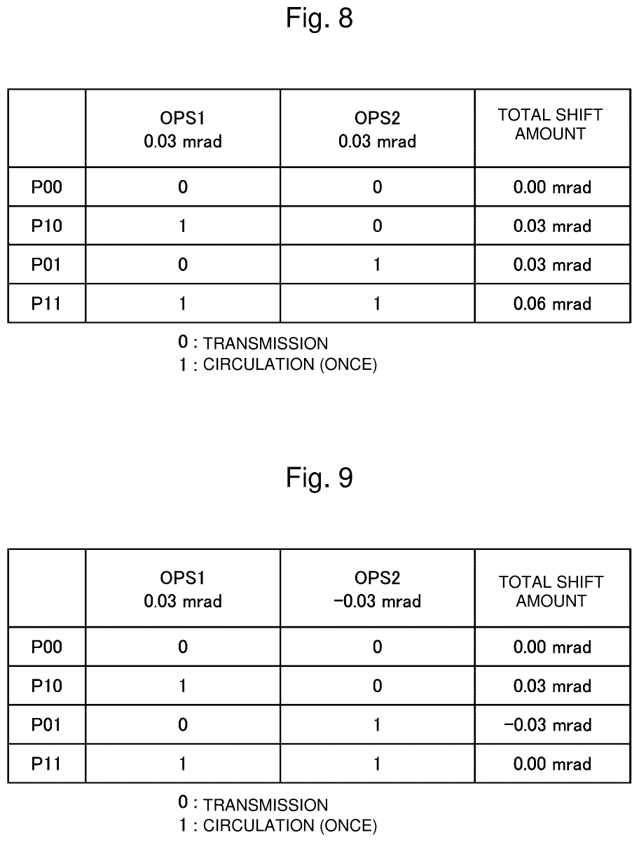

FIG. 8 illustrates an example of an optical path shift by the first and second optical pulse stretchers OPS1 and OPS2. In FIG. 8, a first shift amount in the H direction due to one circulation of the first optical pulse stretcher OPS1 and a second shift amount in the H direction due to one circulation of the second optical pulse stretcher OPS2 are both 0.03 mrad.

In the following description, light beams included in the third pulse laser beam B3 are represented as Pab according to following (a) and (b) depending on whether they have been transmitted or made to circulate once in each of the first and second optical pulse stretchers OPS1 and OPS2.

(a) For the first transmitted light that has transmitted through the first optical pulse stretcher OPS1, a=0 is defined, and for the first once-circulating light that has circulated once in the first optical pulse stretcher OPS1, a=1 is defined.

(b) For second transmitted light that has transmitted through the second optical pulse stretcher OPS2, b=0 is defined, and for second once-circulating light that has circulated once in the second optical pulse stretcher OPS2, b=1 is defined.

The light that has circulated two or more times in at least one optical pulse stretcher is not taken into consideration due to the small energy.

A total shift amount of a light beam P00 is defined as 0.00 mrad. A total shift amount of a light beam P10 is larger than that of the light beam P00 due to one circulation in the first optical pulse stretcher OPS1, and is 0.03 mrad. A total shift amount of a light beam P01 is larger than that of the light beam P00 due to one circulation in the second optical pulse stretcher OPS2, and is 0.03 mrad. A total shift amount of a light beam P11 is larger than that of the light beam P00 due to one circulation each in the first and second optical pulse stretchers OPS1 and OPS2, and is 0.06 mrad. At this time, the total shift amounts of the light beam P10 and the light beam P01 are the same at 0.03 mrad and spatially coincide with each other. In this case, it may not be possible to efficiently reduce the speckle contrast.

FIG. 9 illustrates another example of the optical path shift by the first and second optical pulse stretchers OPS1 and OPS2. In FIG. 9, the first shift amount in the H direction due to one circulation of the first optical pulse stretcher OPS1 is 0.03 mrad, the second shift amount in the H direction due to one circulation of the second optical pulse stretcher OPS2 is −0.03 mrad, and absolute values of the first and second shift amounts are the same, however, the shifts are in directions opposite to each other.

Relative to the total shift amount of the light beam P00 that is 0.00 mrad, the total shift amount of the light beam P10 is 0.03 mrad, the total shift amount of the light beam P01 is −0.03 mrad, and the total shift amount of the light beam P11 is 0.00 mrad. At this time, the total shift amounts of the light beam P00 and the light beam P11 are the same at 0.00 mrad and spatially coincide with each other. In this case, it may not be possible to efficiently reduce the speckle contrast.

### 2. Multiple Optical Pulse Stretchers With Different Absolute Values of Optical Path Shift Amount

### 2.1 Principle

In order to reduce the speckle contrast, it is necessary that the light beams branched and merged by the optical pulse stretcher each have an independent speckle pattern. The speckle pattern is an intensity distribution obtained by squaring an electric field amplitude distribution. Two speckle patterns being independent means that the electric field amplitude distributions are orthogonal, that is, an inner product or a correlation is 0. When the light beams branched and merged by the optical pulse stretcher have N independent speckle patterns and light intensities of the light beams having those speckle patterns are i₁, i₂, . . . , i_{N}, a speckle contrast SC_{OUT} of the light output from the optical pulse stretcher is reduced to a value below in relation to a speckle contrast SC_{IN} of the light incident on the optical pulse stretcher.

$${SC}_{OUT} = {SC}_{I N} \times {( {i}_{1}^{2} + {i}_{2}^{2} + … + {i}_{N}^{2} )}^{1 / 2} / ( {i}_{1} + {i}_{2} + … + {i}_{N} )$$

When the light intensities i₁, i₂, . . . , i_{N} are equal to each other, the speckle contrast SC_{OUT} is reduced to SC_{IN}/(N^{1/2}).

For the speckle patterns of the optical pulses to be independent of each other, a condition is that the optical pulses do not temporally overlap. When the optical pulses temporally overlap, they only change to another speckle pattern due to electric field overlap, without leading to a decrease in the speckle contrast. This is why a part of the light is delayed by the optical pulse stretcher.

When the light beams branched and merged with a time difference by the optical pulse stretcher spatially completely coincide, the speckle patterns become exactly the same, and the speckle contrast does not decrease. When connecting optical pulse stretchers in series, it is necessary to not only spatially shift the transmitted light and the circulating light in each optical pulse stretcher but also ensure that, for example, the light beam P01, which is transmitted in the first optical pulse stretcher OPS1 and made to circulate in the second optical pulse stretcher OPS2, and the light beam P10, which is made to circulate in the first optical pulse stretcher OPS1 and transmitted in the second optical pulse stretcher OPS2, are spatially shifted.

### 2.2 First Example

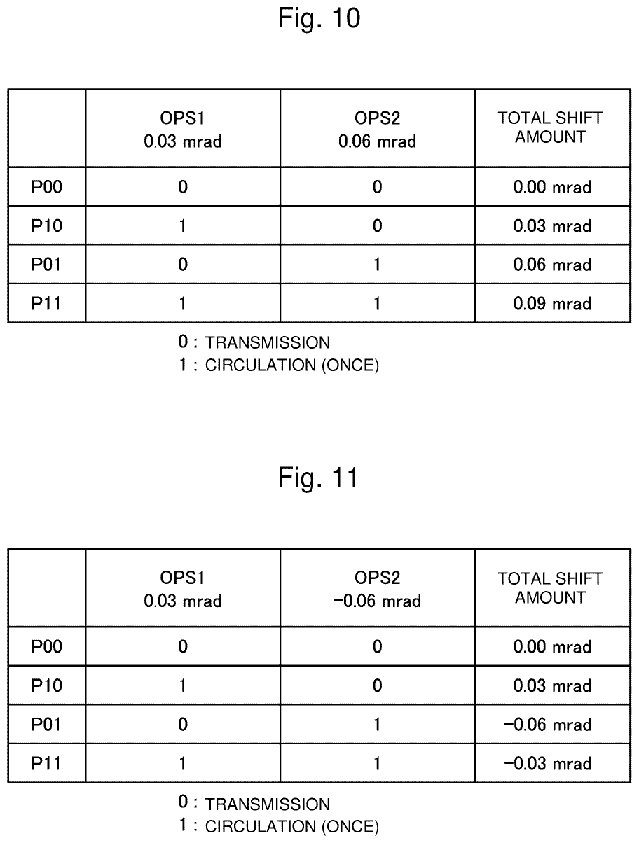

FIG. 10 illustrates the first example of the optical path shift by the first and second optical pulse stretchers OPS1 and OPS2 in a first embodiment. In FIG. 10, the first shift amount in the H direction due to one circulation of the first optical pulse stretcher OPS1 is 0.03 mrad and the second shift amount in the H direction due to one circulation of the second optical pulse stretcher OPS2 is 0.06 mrad.

Relative to the total shift amount of the light beam P00 that is 0.00 mrad, the total shift amount of the light beam P10 is 0.03 mrad, the total shift amount of the light beam P01 is 0.06 mrad, and the total shift amount of the light beam P11 is 0.09 mrad. By making the second shift amount different from the first shift amount in this way, the total shift amounts of the light beams P00, P10, P01, and P11 become different values, forming four optical paths shifted from each other. As a result, the light beams P00, P10, P01, and P11 become the light beams having the independent speckle patterns. When the light intensities of the light beams P00, P10, P01, and P11 are equal to each other, the speckle contrast becomes 0.5 times from the following equation, and the speckle contrast can be efficiently reduced.

$$S {C}_{OUT} = S {C}_{I N} \times {( {1}^{2} + {1}^{2} + {1}^{2} + {1}^{2} )}^{1 / 2} / ( 1 + 1 + 1 + 1 ) = {SC}_{I N} \times 0.5$$

In contrast, in the example described with reference to FIG. 8, the total shift amounts of the light beam P10 and the light beam P01 are the same, and they do not have the independent speckle patterns. The independent speckle patterns are three: the light beam P00, the light beam that is overlap of the light beams P10 and P01, and the light beam P11. In this case, the speckle contrast becomes 0.61 times from the following equation, and an effect of reducing the speckle contrast may be insufficient.

$${SC}_{OUT} = {SC}_{I N} \times {( {1}^{2} + {2}^{2} + {1}^{2} )}^{1 / 2} / ( 1 + 2 + 1 ) = {SC}_{I N} \times 0.61$$

In the example described with reference to FIG. 9 as well, since the total shift amounts of the light beam P00 and the light beam P11 are the same, the effect of reducing the speckle contrast may be insufficient.

### 2.3 Second Example

FIG. 11 illustrates the second example of the optical path shift by the first and second optical pulse stretchers OPS1 and OPS2 in the first embodiment. In FIG. 11, the first shift amount in the H direction due to one circulation of the first optical pulse stretcher OPS1 is 0.03 mrad and the second shift amount in the H direction due to one circulation of the second optical pulse stretcher OPS2 is −0.06 mrad.

Relative to the total shift amount of the light beam P00 that is 0.00 mrad, the total shift amount of the light beam P10 is 0.03 mrad, the total shift amount of the light beam P01 is −0.06 mrad, and the total shift amount of the light beam P11 is −0.03 mrad, forming four optical paths shifted from each other. By making the second shift amount different from the first shift amount in this way, the total shift amounts of the light beams P00, P10, P01, and P11 become different from each other, and the speckle contrast can be efficiently reduced.

As can be seen from the description of FIGS. 8 to 11, the first and second shift amounts only need to have different absolute values, and signs of the shift amounts can be either positive or negative.

It is desirable that the second shift amount is larger than the first shift amount. It is also desirable that the second shift amount is double or more than double the first shift amount. However, in the present disclosure, “double or more than double” does not mean a strict numerical value of 2.0 times or more, and may include, for example, 1.9 times or more.

Since it is necessary to not only spatially shift but also temporally shift the light beams P00, P10, P01, and P11, it is desirable that optical path lengths of delay optical paths of the first and second optical pulse stretchers OPS1 and OPS2 are different from each other. In addition, when shifting the optical path by shifting the traveling direction of the circulating light, the longer the optical path length of the delay optical path, the larger a positional shift of the optical path may become. Further, increasing the optical path shift amount in the preceding optical pulse stretcher may lead to a larger positional shift of the optical path in the subsequent optical pulse stretcher. Therefore, it is desirable that the first optical pulse stretcher OPS1 located in a preceding stage has a smaller optical path shift amount than that of the second optical pulse stretcher OPS2 located in a subsequent stage.

### 2.4 Third Example

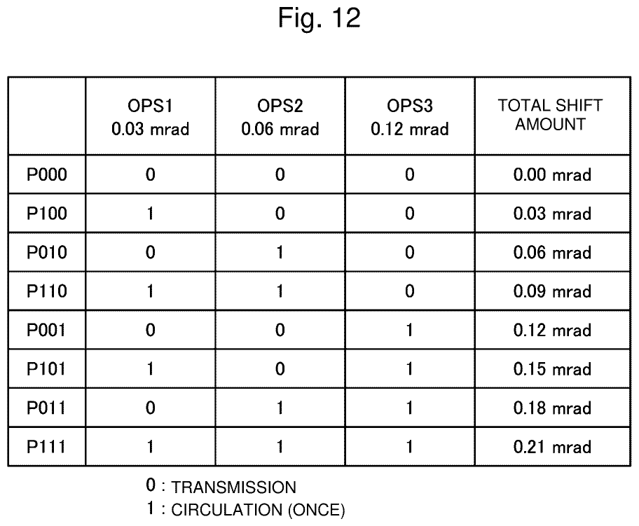

FIG. 12 illustrates an example of the optical path shift by the first to third optical pulse stretchers OPS1 to OPS3 in the first embodiment. In FIG. 12, the first shift amount in the H direction due to one circulation of the first optical pulse stretcher OPS1 is 0.03 mrad, the second shift amount in the H direction due to one circulation of the second optical pulse stretcher OPS2 is 0.06 mrad, and a third shift amount in the H direction due to one circulation of the third optical pulse stretcher OPS3 is 0.12 mrad.

The light beams included in the fourth pulse laser beam B4 are represented as Pabc depending on whether they have been transmitted or made to circulate once in each of the first to third optical pulse stretchers OPS1 to OPS3.

For a and b, it is as described above in (a) and (b).

(c) For third transmitted light that has transmitted through the third optical pulse stretcher OPS3, c=0 is defined, and for third once-circulating light that has circulated once in the third optical pulse stretcher OPS3, c=1 is defined.

Relative to the total shift amount of a light beam P000 that is 0.00 mrad, the total shift amounts of light beams P100, P010, P110, P001, P101, P011, and P111 become larger by 0.03 mrad in this order, forming eight optical paths shifted from each other. By making the first to third shift amounts due to one circulation each in the first to third optical pulse stretchers OPS1 to OPS3 different from each other in this way, the speckle contrast can be efficiently reduced.

It is desirable that the third shift amount is larger than the second shift amount. It is also desirable that the third shift amount is double or more than double the second shift amount. In particular, by doubling the second and third shift amounts, differences in the total shift amounts can be made almost equidistant.

Since it is necessary to not only spatially shift but also temporally shift the light beams P100, P010, P110, P001, P101, P011, and P111, it is desirable that the optical path lengths of the delay optical paths of the first to third optical pulse stretchers OPS1 to OPS3 are different from each other. In addition, it is desirable that the optical path shift amount is smaller for the optical pulse stretcher located in the preceding stage.

### 2.5 Fourth Example

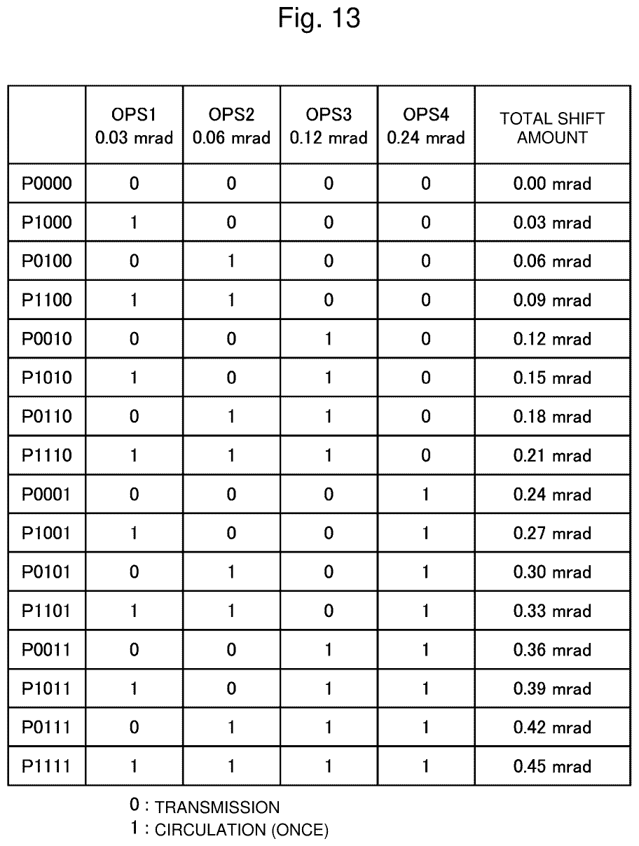

FIG. 13 illustrates an example of the optical path shift by the first to fourth optical pulse stretchers OPS1 to OPS4 in the first embodiment. In FIG. 13, the first shift amount in the H direction due to one circulation of the first optical pulse stretcher OPS1 is 0.03 mrad, the second shift amount in the H direction due to one circulation of the second optical pulse stretcher OPS2 is 0.06 mrad, the third shift amount in the H direction due to one circulation of the third optical pulse stretcher OPS3 is 0.12 mrad, and a fourth shift amount in the H direction due to one circulation of the fourth optical pulse stretcher OPS4 is 0.24 mrad.

The light beams included in the fifth pulse laser beam B5 are represented as Pabcd depending on whether they have been transmitted or made to circulate once in each of the first to fourth optical pulse stretchers OPS1 to OPS4.

For a to c, it is as described above in (a) to (c).

(d) For fourth transmitted light that has transmitted through the fourth optical pulse stretcher OPS4, d=0 is defined, and for fourth once-circulating light that has circulated once in the fourth optical pulse stretcher OPS4, d=1 is defined.

Relative to the total shift amount of a light beam P0000 that is 0.00 mrad, the total shift amounts of light beams P1000, P0100, P1100, P0010, P1010, P0110, P1110, P1001, P0101, P1101, P0011, P1011, P0111, and P1111 become larger by 0.03 mrad in this order, forming sixteen optical paths that shifted from each other. By making the first to fourth shift amounts due to one circulation each in the first to fourth optical pulse stretchers OPS1 to OPS4 different from each other in this way, the speckle contrast can be efficiently reduced.

It is desirable that the fourth shift amount is larger than the third shift amount. It is also desirable that the fourth shift amount is double or more than double the third shift amount. In particular, by doubling the second, third, and fourth shift amounts, the differences in the total shift amounts can be made almost equidistant.

Since it is necessary to not only spatially shift but also temporally shift the light beams P1000, P0100, P1100, P0010, P1010, P0110, P1110, P1001, P0101, P1101, P0011, P1011, P0111, and P1111, it is desirable that the optical path lengths of the delay optical paths of the first to fourth optical pulse stretchers OPS1 to OPS4 are different from each other. In addition, it is desirable that the optical path shift amount is smaller for the optical pulse stretcher located in the preceding stage.

### 2.6 Relationship Between Optical Path Shift Amount and Speckle Pattern Correlation

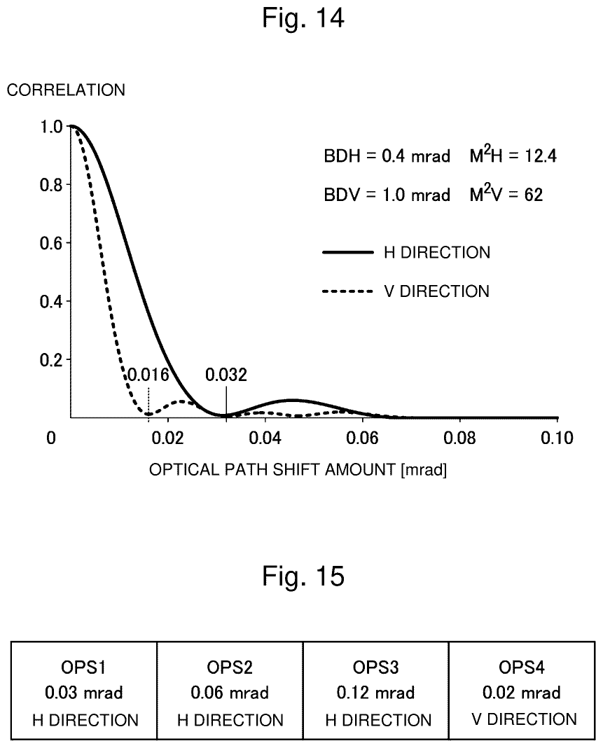

FIG. 14 is a graph illustrating a result of simulating a relationship between the optical path shift amount due to one circulation in the optical pulse stretcher and a correlation of the speckle patterns of the transmitted light and the once-circulating light. The optical path shift amount is represented on a horizontal axis as an angle between the optical axes of the transmitted light and the once-circulating light.

In order to simulate the speckle pattern, first, an electric field of the laser beam is simulated. As described in X. Xiao et al., Optics Express Vol. 14 No. 16, 6989 (2006), the electric field of a multimode laser beam can be calculated using Monte Carlo simulation. Next, the speckle pattern is calculated from the electric field. The speckle pattern can be calculated using the method described in Appendix G of J. W. Goodman, “Speckle phenomena in optics”, Second edition.

When the speckle patterns of the transmitted light and the once-circulating light are I₁ and I₂, respectively, a correlation ρ_{1,2} of the speckle patterns can be calculated using the following equation.

$${ρ}_{1 , 2} = \{ Avg ( {I}_{1} {I}_{2} ) - Avg ( {I}_{1} ) Avg ( {I}_{2} ) \} {/ [ Av g [ {\{ {I}_{1} - Avg ( {I}_{1} ) \}}^{2} ] [ {\{ {I}_{2} - Avg ( {I}_{2} ) \}}^{2} ] ]}^{1 / 2}$$

When the correlation ρ_{1,2} is 1, the two speckle patterns are identical, and the speckle contrast is not reduced at all. When the correlation ρ_{1,2} is 0, there is no correlation, and the effect of reducing the speckle contrast is the highest.

Conditions of the light incident on the optical pulse stretcher are as follows.
H-direction beam width BPH=6 mm
V-direction beam width BPV=12 mm
H-direction beam divergence BDH=0.4 mrad
V-direction beam divergence BDV=1.0 mrad
H-direction M² value M²H=12.4
V-direction M² value M²V=62

As illustrated in FIG. 14, as the optical path shift amount increases from 0, the speckle pattern correlation decreases sharply, and after the speckle pattern correlation approaches 0, even if the optical path shift amount increases further, the speckle pattern correlation changes smoothly around 0.

Considering the optical path shift amount in the H direction, the speckle pattern correlation first approaches 0 when the shift amount is set to 0.032 mrad. This value approximately coincides with BDH/M²H.

Considering the optical path shift amount in the V direction, the speckle pattern correlation first approaches 0 when the shift amount is set to 0.016 mrad. This value approximately coincides with BDV/M²V.

From the above, a guideline for the optical path shift amount in the H direction necessary to reduce the speckle contrast is BDH/M²H, and a guideline for the optical path shift amount in the V direction is BDV/M²V. The V direction will be further described with reference to FIG. 15.

In FIGS. 10 and 11, the optical path shift amount in each optical pulse stretcher is set such that the total shift amounts of the light beams P00, P10, P01, and P11 increase by 0.03 mrad when arranged from the smallest. Thus, the speckle pattern correlation is reduced and the speckle contrast can be efficiently reduced.

In FIG. 12, the total shift amounts of the light beams P100, P010, P110, P001, P101, P011, and P111 also increase by 0.03 mrad in this order. In FIG. 13, the total shift amounts of the light beams P1000, P0100, P1100, P0010, P1010, P0110, P1110, P1001, P0101, P1101, P0011, P1011, P0111, and P1111 also increase by 0.03 mrad in this order. In these cases as well, the speckle contrast can be efficiently reduced.

It has been described that the optical path shift amount in the H direction is set to 0.03 mrad in order to make the speckle pattern correlation be almost 0, however, it is acceptable to have a smaller optical path shift amount as long as the speckle pattern correlation is a sufficiently low value. On the other hand, if the optical path shift amount is too large, beam quality deteriorates. Since a typical H-direction M² value M²H ranges from 10 to 20, for the optical pulse stretcher with the smallest optical path shift amount in the H direction among the optical pulse stretchers, the shift amount may be between 1/20 and 1/10 of the H-direction beam divergence BDH.

It is desirable that, for the optical pulse stretcher with the largest optical path shift amount in the H direction among the optical pulse stretchers, the shift amount is less than the H-direction beam divergence BDH.

It is desirable that a difference between the total shift amount in the H direction of each of the light beams P100, P010, P110, P001, P101, P011, and P111 illustrated in FIG. 12 and the total shift amount in the H direction of the other light beams is at least 1/20 of the H-direction beam divergence BDH. It is desirable that a difference between the total shift amount in the H direction of each of the light beams P1000, P0100, P1100, P0010, P1010, P0110, P1110, P1001, P0101, P1101, P0011, P1011, P0111, and P1111 illustrated in FIG. 13 and the total shift amount in the H direction of the other light beams is at least 1/20 of the H-direction beam divergence BDH.

### 2.7 Effect

According to the first embodiment, the laser apparatus 100 includes the laser oscillator MO, the first optical pulse stretcher OPS1, and the second optical pulse stretcher OPS2. The laser oscillator MO includes the optical resonator and the pair of electrodes 11a and 11b that apply a voltage to the laser gas to cause the discharge, and outputs the first pulse laser beam B1. The first optical pulse stretcher OPS1 is disposed in the optical path of the first pulse laser beam B1 and outputs the second pulse laser beam B2 for which the pulse time width of the first pulse laser beam B1 is extended by transmitting a part of the first pulse laser beam B1, making the other part circulate once, and outputting the first transmitted light and the first once-circulating light. The first optical pulse stretcher OPS1 is configured such that the optical path of the first transmitted light and the optical path of the first once-circulating light spatially partially overlap with the first shift amount in a first direction. The second optical pulse stretcher OPS2 is disposed in the optical path of the second pulse laser beam B2 and outputs the third pulse laser beam B3 for which the pulse time width of the second pulse laser beam B2 is extended by transmitting a part of the second pulse laser beam B2, making the other part circulate once, and outputting the second transmitted light and the second once-circulating light. The second optical pulse stretcher OPS2 is configured such that the optical path of the second transmitted light and the optical path of the second once-circulating light spatially partially overlap with the second shift amount, which is different from the first shift amount, in the first direction.

Even when the optical pulse stretchers are connected in series and the optical path is shifted by each optical pulse stretcher, if the optical path shift amounts in the optical pulse stretchers are the same, the optical path shifts may be offset. When the shift amounts are made different, a possibility that the optical path shifts by the optical pulse stretchers are offset is lowered, and the speckles are effectively reduced.

According to the first embodiment, the second shift amount is larger than the first shift amount.

Accordingly, by reducing the optical path shift in the preceding optical pulse stretcher, it is possible to suppress excessive beam spreading when output from the laser apparatus 100.

According to the first embodiment, the second shift amount is double or more than double the first shift amount.

Accordingly, by making the optical path shift amount in the subsequent optical pulse stretcher double or more than double that in the preceding stage, the optical path shifts by the optical pulse stretchers are prevented from being offset, and the speckles can be more effectively reduced.

According to the first embodiment, the laser apparatus 100 includes the third optical pulse stretcher OPS3 that is disposed in the optical path of the third pulse laser beam B3 and outputs the fourth pulse laser beam B4 for which the pulse time width of the third pulse laser beam B3 is extended by transmitting a part of the third pulse laser beam B3, making the other part circulate once, and outputting the third transmitted light and the third once-circulating light. The third optical pulse stretcher OPS3 is configured such that the optical path of the third transmitted light and the optical path of the third once-circulating light spatially partially overlap with the third shift amount, which is different from both the first and second shift amounts, in the first direction.

Accordingly, by connecting three or more optical pulse stretchers with the optical path shift amounts different from each other in series, the speckles can be further reduced.

According to the first embodiment, when the light beams included in the fourth pulse laser beam B4 are represented as Pabc depending on whether they have been transmitted or made to circulate once in each of the first, second, and third optical pulse stretchers OPS1, OPS2, and OPS3, the optical paths of the light beams P000, P100, P010, P110, P001, P101, P011, and P111 are shifted from each other. Here, a=0 is defined for the first transmitted light, a=1 is defined for the first once-circulating light, b=0 is defined for the second transmitted light, b=1 is defined for the second once-circulating light, c=0 is defined for the third transmitted light, and c=1 is defined for the third once-circulating light.

Accordingly, since the light beams included in the fourth pulse laser beam B4 have eight optical paths shifted from each other, the speckles can be effectively reduced.

According to the first embodiment, the second shift amount is double or more than double the first shift amount, and the third shift amount is double or more than double the second shift amount.

Accordingly, by making the third shift amount in the third optical pulse stretcher OPS3 double or more than double the second shift amount in the second optical pulse stretcher OPS2, the optical path shifts by the optical pulse stretchers are prevented from being offset, and the speckles can be more effectively reduced.

According to the first embodiment, the laser apparatus 100 includes the fourth optical pulse stretcher OPS4 that is disposed in the optical path of the fourth pulse laser beam B4 and outputs the fifth pulse laser beam B5 for which the pulse time width of the fourth pulse laser beam B4 is extended by transmitting a part of the fourth pulse laser beam B4, making the other part circulate once, and outputting the fourth transmitted light and the fourth once-circulating light. The fourth optical pulse stretcher OPS4 is configured such that the optical path of the fourth transmitted light and the optical path of the fourth once-circulating light spatially partially overlap with the fourth shift amount in the first direction. The fourth shift amount is double or more than double the third shift amount.

Accordingly, by making the fourth shift amount in the fourth optical pulse stretcher OPS4 double or more than double the third shift amount in the third optical pulse stretcher OPS3, the speckles can be more effectively reduced.

According to the first embodiment, the first direction is the H direction, which is perpendicular to both the direction of the discharge and the direction of the optical path axis of the optical resonator.

For the first pulse laser beam B1, the M² value M²V in the V direction, which is parallel to the direction of the discharge, is larger than the M² value M²H in the H direction, which is perpendicular to the direction of the discharge, and the beam quality is low. By shifting the optical path in the H direction to lower the beam quality in the H direction, it is possible to alleviate anisotropy of the beam quality and to suppress deterioration of the beam quality in the V direction.

According to the first embodiment, the optical path shift between the second transmitted light and the second once-circulating light and the optical path shift between the first transmitted light and the first once-circulating light include a shift of a light traveling direction, respectively. Further, the smaller of the second shift amount and the first shift amount is between 1/20 and 1/10 of the beam divergence BDH in the first direction of the first pulse laser beam B1.

Accordingly, by setting the optical path shift amount to reduce the speckle pattern correlation, the speckles can be effectively reduced.

According to the first embodiment, the larger of the second shift amount and the first shift amount is less than the beam divergence BDH in the first direction of the first pulse laser beam B1.

Accordingly, by overlapping a part of the beam, it is possible to reduce the speckles and to suppress the excessive beam spreading and the deterioration of the beam quality.

According to the first embodiment, the laser apparatus 100 includes the third optical pulse stretcher OPS3 that is disposed in the optical path of the third pulse laser beam B3 and outputs the fourth pulse laser beam B4 for which the pulse time width of the third pulse laser beam B3 is extended by transmitting a part of the third pulse laser beam B3, making the other part circulate once, and outputting the third transmitted light and the third once-circulating light. The third optical pulse stretcher OPS3 is configured such that the optical path of the third transmitted light and the optical path of the third once-circulating light spatially partially overlap. When the light beams included in the fourth pulse laser beam B4 are represented as Pabc depending on whether they have been transmitted or made to circulate once in each of the first, second, and third optical pulse stretchers OPS1, OPS2, and OPS3, the difference between the total shift amount in the first direction of the optical path of each of the light beams P000, P100, P010, P110, P001, P101, P011, and P111 and the total shift amount in the first direction of the other optical paths is at least 1/20 of the beam divergence BDH in the first direction of the first pulse laser beam B1. Here, a=0 is defined for the first transmitted light, a=1 is defined for the first once-circulating light, b=0 is defined for the second transmitted light, b=1 is defined for the second once-circulating light, c=0 is defined for the third transmitted light, and c=1 is defined for the third once-circulating light.

Accordingly, it is possible to reduce the correlation of the eight light speckle patterns.

In other respects, the first embodiment is similar to the comparative example.

### 3. Optical Pulse Stretcher That Shifts Optical Path in V Direction

### 3.1 Configuration

FIG. 15 illustrates an example of the optical path shift by the first to fourth optical pulse stretchers OPS1 to OPS4 in a second embodiment. FIG. 15 illustrates the first to fourth shift amounts and shift directions due to one circulation each in the first to fourth optical pulse stretchers OPS1 to OPS4. While the fourth optical pulse stretcher OPS4 shifts the optical path in the H direction in FIG. 13, it is different in FIG. 15 in that the fourth optical pulse stretcher OPS4 shifts the optical path in the V direction.

While FIG. 15 illustrates a case where the fourth optical pulse stretcher OPS4 shifts the optical path in the V direction, the present disclosure is not limited thereto. In FIG. 15, the fourth optical pulse stretcher OPS4 may be removed, and instead, a non-illustrated optical pulse stretcher that shifts the optical path in the V direction may be disposed between the output coupling mirror 15 and the first optical pulse stretcher OPS1, between the first optical pulse stretcher OPS1 and the second optical pulse stretcher OPS2, or between the second optical pulse stretcher OPS2 and the third optical pulse stretcher OPS3.

As described with reference to FIG. 14, the guideline for the optical path shift amount in the V direction necessary to reduce the speckle contrast is BDV/M²V, and its value is approximately 0.016 mrad. Therefore, it is preferable to shift the optical path in the V direction by about 0.016 mrad, for example, 0.02 mrad. The shift amount of the optical pulse stretcher that shifts the optical path in the V direction may be smaller than the shift amount of any of the optical pulse stretchers that shift the optical path in the H direction.

As illustrated in FIG. 14, in an excimer laser apparatus, the V-direction M² value M²V is generally larger than the H-direction M² value M²H, and the beam quality in the V direction is lower than the beam quality in the H direction. Since the beam quality in the V direction further decreases when the optical path is shifted in the V direction by the optical pulse stretcher, it is desirable to make the number of the optical pulse stretchers that shift the optical path in the V direction smaller than the number of the optical pulse stretchers that shift the optical path in the H direction. For example, when using a total of four stages of optical pulse stretchers as illustrated in FIG. 15, three stages of the optical pulse stretchers shift the optical path differently in the H direction, and one stage of the optical pulse stretcher shifts the optical path in the V direction. Alternatively, when using a total of three stages of optical pulse stretchers, two stages of the optical pulse stretchers shift the optical path differently in the H direction, and one stage of the optical pulse stretcher shifts the optical path in the V direction.

It has been described that the optical path shift amount in the V direction is set to 0.02 mrad in order to make the speckle pattern correlation be almost 0, however, it is acceptable to have a smaller optical path shift amount as long as the speckle pattern correlation is a sufficiently low value. On the other hand, if the optical path shift amount is too large, the beam quality deteriorates. Since a typical V-direction M² value M²V ranges from 40 to 80, the optical path shift amount in the V direction may be between 1/80 and 1/40 of the V-direction beam divergence BDV.

### 3.2 Effect

According to the second embodiment, the laser apparatus 100 includes the third optical pulse stretcher OPS3 that is disposed in the optical path of the third pulse laser beam B3 and outputs the fourth pulse laser beam B4 for which the pulse time width of the third pulse laser beam B3 is extended by transmitting a part of the third pulse laser beam B3, making the other part circulate once, and outputting the third transmitted light and the third once-circulating light. The third optical pulse stretcher OPS3 is configured such that the optical path of the third transmitted light and the optical path of the third once-circulating light spatially partially overlap with the third shift amount in a second direction. The first direction is the H direction, which is perpendicular to both the direction of the discharge and the direction of the optical axis of the optical resonator, and the second direction is the V direction, which is parallel to the direction of the discharge.

Accordingly, by shifting and overlapping the beams not only in the H direction but also in the V direction, it is possible to reduce the speckles and to suppress the excessive beam spreading in the H direction and the deterioration of the beam quality. In addition, by making the number of the optical pulse stretchers that shift the optical path in the V direction smaller than the number of the optical pulse stretchers that shift the optical path in the H direction, it is possible to suppress the deterioration of the beam quality in the V direction.

According to the second embodiment, the third shift amount is smaller than both the first and second shift amounts.

Accordingly, by reducing the optical path shift amount in the V direction, it is possible to suppress the deterioration of the beam quality in the V direction.

According to the second embodiment, the optical path shift between the third transmitted light and the third once-circulating light, the optical path shift between the second transmitted light and the second once-circulating light, and the optical path shift between the first transmitted light and the first once-circulating light include the shift of the light traveling direction, respectively. Further, the third shift amount is between 1/80 and 1/40 of the beam divergence BDV in the second direction of the first pulse laser beam B1.

Accordingly, by setting the V-direction shift amount to reduce the speckle pattern correlation, the speckles can be effectively reduced.

According to the second embodiment, the laser apparatus 100 includes the third optical pulse stretcher OPS3 that is disposed in the optical path of the third pulse laser beam B3 and outputs the fourth pulse laser beam B4 for which the pulse time width of the third pulse laser beam B3 is extended by transmitting a part of the third pulse laser beam B3, making the other part circulate once, and outputting the third transmitted light and the third once-circulating light, and the fourth optical pulse stretcher OPS4 that is disposed in the optical path of the fourth pulse laser beam B4 and outputs the fifth pulse laser beam B5 for which the pulse time width of the fourth pulse laser beam B4 is extended by transmitting a part of the fourth pulse laser beam B4, making the other part circulate once, and outputting the fourth transmitted light and the fourth once-circulating light. The third optical pulse stretcher OPS3 is configured such that the optical path of the third transmitted light and the optical path of the third once-circulating light spatially partially overlap, and the fourth optical pulse stretcher OPS4 is configured such that the optical path of the fourth transmitted light and the optical path of the fourth once-circulating light spatially partially overlap. Further, one of the third and fourth optical pulse stretchers OPS3 and OPS4 is configured to shift the optical path in the first direction by a shift amount different from both the first and second shift amounts by one circulation, and the other is configured to shift the optical path in the second direction by one circulation, where the first direction is the H direction, which is perpendicular to both the direction of the discharge and the direction of the optical axis of the optical resonator and the second direction is the V direction, which is parallel to the direction of the discharge.

Accordingly, even when using four optical pulse stretchers, by shifting and overlapping the beams not only in the H direction but also in the V direction, it is possible to reduce the speckles and to suppress the excessive beam spreading in the H direction and the deterioration of the beam quality. In addition, by making the number of the optical pulse stretchers that shift the optical path in the V direction smaller than the number of the optical pulse stretchers that shift the optical path in the H direction, it is possible to suppress the deterioration of the beam quality in the V direction.

In other respects, the second embodiment is similar to the first embodiment.

### 4. Optical Pulse Stretcher Where Optical Path Shift Includes Shift of Light Output Position

### 4.1 Configuration

FIG. 16 schematically illustrates an example of the optical pulse stretcher included in a third embodiment. While the optical path shift includes the shift of the light traveling direction in the fourth optical pulse stretcher OPS4 described with reference to FIG. 3, the optical path shift includes a shift of a light output position in the fourth optical pulse stretcher OPS4 illustrated in FIG. 16. The fifth pulse laser beam B5 output from the fourth optical pulse stretcher OPS4 illustrated in FIG. 16 may include the transmitted light B50, the once-circulating light B51, and the twice-circulating light B52 that are parallel to each other. Such an optical path shift is realized by a disposition of the concave mirrors 184b to 184e.

While FIG. 16 illustrates a case where the light output position shifts in the V direction, the light output position may also shift in the H direction.

For example, the optical path shift in each of the first and second optical pulse stretchers OPS1 and OPS2 may include the shift of the light output position, and the first and second shift amounts in the first and second optical pulse stretchers OPS1 and OPS2 may be different from each other.

When the third optical pulse stretcher OPS3 is further provided, the optical path shift in the third optical pulse stretcher OPS3 may include the shift of the light output position, and the direction of the shift may be either the H direction or the V direction.

When the fourth optical pulse stretcher OPS4 is further provided, the optical path shift in each of the third and fourth optical pulse stretchers OPS3 and OPS4 may include the shift of the light output position. Both the third and fourth optical pulse stretchers OPS3 and OPS4 may shift the optical path in the H direction, or either one may shift the optical path in the H direction while the other shifts the optical path in the V direction.

FIG. 17 illustrates an example of the optical path shift by the first to fourth optical pulse stretchers OPS1 to OPS4 in the third embodiment. FIG. 17 illustrates the first to fourth shift amounts and the shift directions due to one circulation each in the first to fourth optical pulse stretchers OPS1 to OPS4.

In the example illustrated in FIG. 17, the first optical pulse stretcher OPS1 shifts the optical path in the H direction by 0.5 mm, the second optical pulse stretcher OPS2 shifts the optical path in the H direction by 1.0 mm, the third optical pulse stretcher OPS3 shifts the optical path in the H direction by 2.0 mm, and the fourth optical pulse stretcher OPS4 shifts the optical path in the V direction by 0.2 mm.

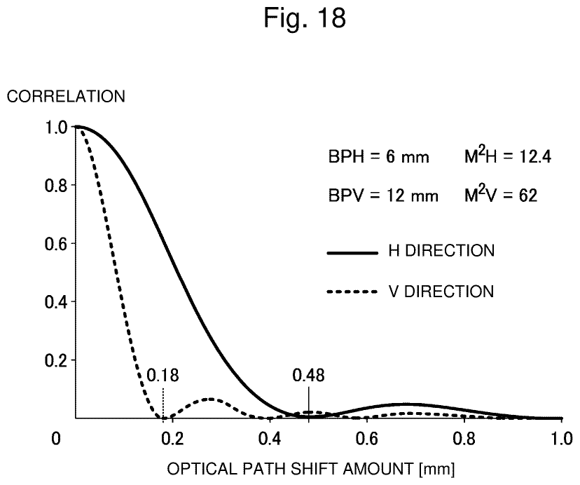

FIG. 18 is a graph illustrating a result of simulating the relationship between the optical path shift amount due to one circulation in the optical pulse stretcher and the correlation of the speckle patterns of the transmitted light and the once-circulating light. The optical path shift amount is represented on a horizontal axis as a distance between the optical axes of the transmitted light and the once-circulating light that are parallel to each other. The method of simulation and the conditions of the light incident on the optical pulse stretcher are the same as those described with reference to FIG. 14.

Considering the optical path shift amount in the H direction, the speckle pattern correlation first approaches 0 when the shift amount is set to 0.48 mm. This value approximately coincides with BPH/M²H.

Considering the optical path shift amount in the V direction, the speckle pattern correlation first approaches 0 when the shift amount is set to 0.18 mm. This value approximately coincides with BPV/M²V.

From the above, the guideline for the optical path shift amount in the H direction necessary to reduce the speckle contrast is BPH/M²H, and the guideline for the optical path shift amount in the V direction is BPV/M²V.

FIG. 17 illustrates the example where the optical path shift amount in the H direction in the first optical pulse stretcher OPS1 is set to 0.5 mm in order to make the speckle pattern correlation be almost 0, however, it is acceptable to have a smaller optical path shift amount as long as the speckle pattern correlation is a sufficiently low value. On the other hand, if the optical path shift amount is too large, the beam quality deteriorates. Since the typical H-direction M² value M²H ranges from 10 to 20, for the optical pulse stretcher with the smallest optical path shift amount in the H direction among the optical pulse stretchers, the shift amount may be between 1/20 and 1/10 of the H-direction beam width BPH.

It is desirable that, for the optical pulse stretcher with the largest optical path shift amount in the H direction among the optical pulse stretchers, the shift amount is less than the H-direction beam width BPH.

When shifting the light output position in each of the first to third optical pulse stretchers OPS1 to OPS3 in FIG. 12, it is desirable that the difference between the total shift amount in the H direction of each of the light beams P100, P010, P110, P001, P101, P011, and P111 and the total shift amount in the H direction of the other light beams is at least 1/20 of the H-direction beam width BPH. When shifting the light output position in each of the first to fourth optical pulse stretchers OPS1 to OPS4 in FIG. 13, it is desirable that the difference between the total shift amount in the H direction of each of the light beams P1000, P0100, P1100, P0010, P1010, P0110, P1110, P1001, P0101, P1101, P0011, P1011, P0111, and P1111 and the total shift amount in the H direction of the other light beams is at least 1/20 of the H-direction beam width BPH.

FIG. 17 illustrates the example where the optical path shift amount in the V direction in the fourth optical pulse stretcher OPS4 is set to 0.2 mm in order to make the speckle pattern correlation be almost 0, however, it is acceptable to have a smaller optical path shift amount as long as the speckle pattern correlation is a sufficiently low value. On the other hand, if the optical path shift amount is too large, the beam quality deteriorates. Since the typical V-direction M² value M²V ranges from 40 to 80, the optical path shift amount in the V direction may be between 1/80 and 1/40 of the V-direction beam width BPV.

While a case where the four optical pulse stretchers each shift the light output position has been described in FIG. 17, it is also possible for some of the four optical pulse stretchers to shift the light output position while the others shift the light traveling direction. In addition, one optical pulse stretcher may shift both the light output position and the traveling direction.

### 4.2 Effect

According to the third embodiment, the optical path shift between the second transmitted light and the second once-circulating light and the optical path shift between the first transmitted light and the first circulating light include the shift of the light output position, respectively. Further, the smaller of the second shift amount and the first shift amount is between 1/20 and 1/10 of the beam width BPH in the first direction of the first pulse laser beam B1.

Accordingly, by setting the optical path shift amount to reduce the speckle pattern correlation, the speckles can be effectively reduced.

According to the third embodiment, the larger of the second shift amount and the first shift amount is less than the beam width BPH in the first direction of the first pulse laser beam B1.

Accordingly, by overlapping a part of the beam, it is possible to reduce the speckles and to suppress the excessive beam spreading and the deterioration of the beam quality.

According to the third embodiment, the laser apparatus 100 includes the third optical pulse stretcher OPS3 that is disposed in the optical path of the third pulse laser beam B3 and outputs the fourth pulse laser beam B4 for which the pulse time width of the third pulse laser beam B3 is extended by transmitting a part of the third pulse laser beam B3, making the other part circulate once, and outputting the third transmitted light and the third once-circulating light. The third optical pulse stretcher OPS3 is configured such that the optical path of the third transmitted light and the optical path of the third once-circulating light spatially partially overlap. Further, when the light beams included in the fourth pulse laser beam B4 are represented as Pabc depending on whether they have been transmitted or made to circulate once in each of the first, second, and third optical pulse stretchers OPS1, OPS2, and OPS3, the difference between the total shift amount in the first direction of the optical path of each of the light beams P000, P100, P010, P110, P001, P101, P011, and P111 and the total shift amount in the first direction of the other optical paths is at least 1/20 of the beam width BPH in the first direction of the first pulse laser beam B1. Here, a=0 is defined for the first transmitted light, a=1 is defined for the first once-circulating light, b=0 is defined for the second transmitted light, b=1 is defined for the second once-circulating light, c=0 is defined for the third transmitted light, and c=1 is defined for the third once-circulating light.

Accordingly, it is possible to reduce the correlation of the eight light speckle patterns.

According to the third embodiment, the optical path shift between the third transmitted light and the third once-circulating light, the optical path shift between the second transmitted light and the second once-circulating light, and the optical path shift between the first transmitted light and the first once-circulating light include the shift of the light output position, respectively. Further, the third shift amount is between 1/80 and 1/40 of the beam width BPV in the second direction of the first pulse laser beam B1.

Accordingly, by setting the optical path shift amount to reduce the speckle pattern correlation, the speckles can be effectively reduced.

In other respects, the third embodiment is the same as the first and second embodiments.

### 5. Others

### 5.1 Modifications of Optical Pulse Stretcher

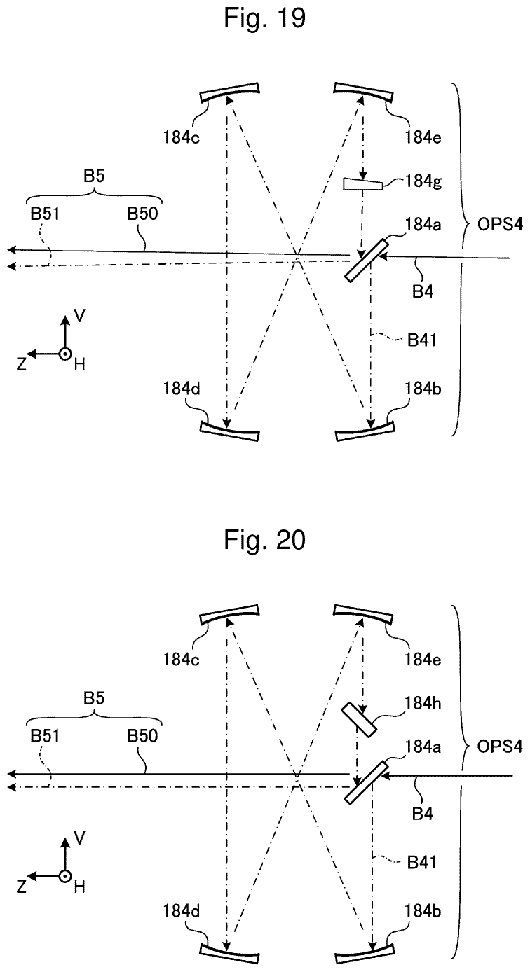

FIG. 19 schematically illustrates a first modification of the optical pulse stretcher. While the fourth optical pulse stretcher OPS4 described with reference to FIG. 3 includes the actuator 184f, the fourth optical pulse stretcher OPS4 illustrated in FIG. 19 includes a wedge substrate 184g. The wedge substrate 184g is a plate that is provided with two non-parallel planes and has a high transmittance, and by changing the traveling direction of the light B41, causes the shift of the traveling direction between the transmitted light B50 and the once-circulating light B51. A posture of the wedge substrate 184g may be changed by a non-illustrated actuator to allow fine adjustment of the shift amount of the traveling direction.

FIG. 20 schematically illustrates a second modification of the optical pulse stretcher. While the fourth optical pulse stretcher OPS4 described with reference to FIG. 16 includes the actuator 184f, the fourth optical pulse stretcher OPS4 illustrated in FIG. 20 includes a parallel plane substrate 184h. The parallel plane substrate 184h is a plate that is provided with two parallel planes and has a high transmittance, and by shifting the optical axis of light B41, causes the shift of the output position between the transmitted light B50 and the once-circulating light B51. A posture of the parallel plane substrate 184h may be changed by a non-illustrated actuator to allow fine adjustment of the shift amount of the output position.

### 5.2 Supplement

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it is also obvious for those skilled in the art that embodiments of the present disclosure would be appropriately combined.

The terms used throughout the present specification and the appended claims should be interpreted as “non-limiting” terms unless clearly described. For example, terms such as “include”, “have”, “comprise”, “contain” and the like should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of “A”, “B”, “C”, “A+B”, “A+C”, “B+C”, and “A+B+C” as well as to include combinations of any thereof and any other than “A”, “B”, and “C”.

What is claimed is:

1. A laser apparatus comprising:
a laser oscillator including an optical resonator and a pair of electrodes that apply a voltage to a laser gas to cause discharge, and configured to output a first pulse laser beam;
a first optical pulse stretcher disposed in an optical path of the first pulse laser beam, configured to output a second pulse laser beam for which a pulse time width of the first pulse laser beam is extended by transmitting a part of the first pulse laser beam, making the other part circulate once, and outputting first transmitted light and first once-circulating light, and configured such that an optical path of the first transmitted light and an optical path of the first once-circulating light spatially partially overlap with a first shift amount in a first direction; and
a second optical pulse stretcher disposed in an optical path of the second pulse laser beam, configured to output a third pulse laser beam for which a pulse time width of the second pulse laser beam is extended by transmitting a part of the second pulse laser beam, making the other part circulate once, and outputting second transmitted light and second once-circulating light, and configured such that an optical path of the second transmitted light and an optical path of the second once-circulating light spatially partially overlap with a second shift amount, which is different from the first shift amount, in the first direction.

2. The laser apparatus according to claim 1, wherein
the second shift amount is larger than the first shift amount.

3. The laser apparatus according to claim 1, wherein
the second shift amount is double or more than double the first shift amount.

4. The laser apparatus according to claim 1, further comprising
a third optical pulse stretcher disposed in an optical path of the third pulse laser beam, configured to output a fourth pulse laser beam for which a pulse time width of the third pulse laser beam is extended by transmitting a part of the third pulse laser beam, making the other part circulate once, and outputting third transmitted light and third once-circulating light, and configured such that an optical path of the third transmitted light and an optical path of the third once-circulating light spatially partially overlap with a third shift amount, which is different from both the first and second shift amounts, in the first direction.

5. The laser apparatus according to claim 4, wherein,
when a=0 is defined for the first transmitted light,
a=1 is defined for the first once-circulating light,
b=0 is defined for the second transmitted light,
b=1 is defined for the second once-circulating light,
c=0 is defined for the third transmitted light,
c=1 is defined for the third once-circulating light, and
light beams included in the fourth pulse laser beam are represented as Pabc depending on whether they have been transmitted or made to circulate once in each of the first, second, and third optical pulse stretchers,
optical paths of light beams P000, P100, P010, P110, P001, P101, P011, and P111 are shifted from each other.

6. The laser apparatus according to claim 4, wherein
the second shift amount is double or more than double the first shift amount, and
the third shift amount is double or more than double the second shift amount.

7. The laser apparatus according to claim 6, further comprising
a fourth optical pulse stretcher disposed in an optical path of the fourth pulse laser beam, configured to output a fifth pulse laser beam for which a pulse time width of the fourth pulse laser beam is extended by transmitting a part of the fourth pulse laser beam, making the other part circulate once, and outputting fourth transmitted light and fourth once-circulating light, and configured such that an optical path of the fourth transmitted light and an optical path of the fourth once-circulating light spatially partially overlap with a fourth shift amount in the first direction, wherein
the fourth shift amount is double or more than double the third shift amount.

8. The laser apparatus according to claim 1, wherein
the first direction is perpendicular to both a direction of the discharge and a direction of an optical path axis of the optical resonator.

9. The laser apparatus according to claim 8, wherein
an optical path shift between the second transmitted light and the second once-circulating light and an optical path shift between the first transmitted light and the first once-circulating light include a shift of a light traveling direction, respectively, and
the smaller of the second shift amount and the first shift amount is between 1/20 and 1/10 of a beam divergence in the first direction of the first pulse laser beam.

10. The laser apparatus according to claim 9, wherein
the larger of the second shift amount and the first shift amount is less than the beam divergence in the first direction of the first pulse laser beam.

11. The laser apparatus according to claim 8, further comprising
a third optical pulse stretcher disposed in an optical path of the third pulse laser beam, configured to output a fourth pulse laser beam for which a pulse time width of the third pulse laser beam is extended by transmitting a part of the third pulse laser beam, making the other part circulate once, and outputting third transmitted light and third once-circulating light, and configured such that an optical path of the third transmitted light and an optical path of the third once-circulating light spatially partially overlap, wherein
when a=0 is defined for the first transmitted light,
a=1 is defined for the first once-circulating light,
b=0 is defined for the second transmitted light,
b=1 is defined for the second once-circulating light,
c=0 is defined for the third transmitted light,
c=1 is defined for the third once-circulating light, and
light beams included in the fourth pulse laser beam are represented as Pabc depending on whether they have been transmitted or made to circulate once in each of the first, second, and third optical pulse stretchers,
a difference between a total shift amount in the first direction of an optical path of each of light beams P000, P100, P010, P110, P001, P101, P011, and P111 and a total shift amount in the first direction of the other optical paths is at least 1/20 of a beam divergence in the first direction of the first pulse laser beam.

12. The laser apparatus according to claim 8, wherein
an optical path shift between the second transmitted light and the second once-circulating light and an optical path shift between the first transmitted light and the first once-circulating light include a shift of a light output position, respectively, and
the smaller of the second shift amount and the first shift amount is between 1/20 and 1/10 of a beam width in the first direction of the first pulse laser beam.

13. The laser apparatus according to claim 12, wherein
the larger of the second shift amount and the first shift amount is less than the beam width in the first direction of the first pulse laser beam.

14. The laser apparatus according to claim 8, further comprising
a third optical pulse stretcher disposed in an optical path of the third pulse laser beam, configured to output a fourth pulse laser beam for which a pulse time width of the third pulse laser beam is extended by transmitting a part of the third pulse laser beam, making the other part circulate once, and outputting third transmitted light and third once-circulating light, and configured such that an optical path of the third transmitted light and an optical path of the third once-circulating light spatially partially overlap, wherein
when a=0 is defined for the first transmitted light,
a=1 is defined for the first once-circulating light,
b=0 is defined for the second transmitted light,
b=1 is defined for the second once-circulating light,
c=0 is defined for the third transmitted light,
c=1 is defined for the third once-circulating light, and
light beams included in the fourth pulse laser beam are represented as Pabc depending on whether they have been transmitted or made to circulate once in each of the first, second, and third optical pulse stretchers,
a difference between a total shift amount in the first direction of an optical path of each of light beams P000, P100, P010, P110, P001, P101, P011, and P111 and a total shift amount in the first direction of the other optical paths is at least 1/20 of a beam width in the first direction of the first pulse laser beam.

15. The laser apparatus according to claim 1, further comprising
a third optical pulse stretcher disposed in an optical path of the third pulse laser beam, configured to output a fourth pulse laser beam for which a pulse time width of the third pulse laser beam is extended by transmitting a part of the third pulse laser beam, making the other part circulate once, and outputting third transmitted light and third once-circulating light, and configured such that an optical path of the third transmitted light and an optical path of the third once-circulating light spatially partially overlap with a third shift amount in a second direction, wherein
the first direction is perpendicular to both a direction of the discharge and a direction of an optical path axis of the optical resonator, and
the second direction is the direction of the discharge.

16. The laser apparatus according to claim 15, wherein
the third shift amount is smaller than both the first and second shift amounts.

17. The laser apparatus according to claim 15, wherein
an optical path shift between the third transmitted light and the third once-circulating light, an optical path shift between the second transmitted light and the second once-circulating light, and an optical path shift between the first transmitted light and the first once-circulating light include a shift of a light traveling direction, respectively, and
the third shift amount is between 1/80 and 1/40 of a beam divergence in the second direction of the first pulse laser beam.

18. The laser apparatus according to claim 15, wherein
an optical path shift between the third transmitted light and the third once-circulating light, an optical path shift between the second transmitted light and the second once-circulating light, and an optical path shift between the first transmitted light and the first once-circulating light include a shift of a light output position, respectively, and
the third shift amount is between 1/80 and 1/40 of a beam width in the second direction of the first pulse laser beam.

19. The laser apparatus according to claim 1, further comprising:
a third optical pulse stretcher disposed in an optical path of the third pulse laser beam, configured to output a fourth pulse laser beam for which a pulse time width of the third pulse laser beam is extended by transmitting a part of the third pulse laser beam, making the other part circulate once, and outputting third transmitted light and third once-circulating light, and configured such that an optical path of the third transmitted light and an optical path of the third once-circulating light spatially partially overlap; and
a fourth optical pulse stretcher disposed in an optical path of the fourth pulse laser beam, configured to output a fifth pulse laser beam for which a pulse time width of the fourth pulse laser beam is extended by transmitting a part of the fourth pulse laser beam, making the other part circulate once, and outputting fourth transmitted light and fourth once-circulating light, and configured such that an optical path of the fourth transmitted light and an optical path of the fourth once-circulating light spatially partially overlap, wherein
one of the third and fourth optical pulse stretchers is configured to shift the optical path in the first direction by a shift amount different from both the first and second shift amounts by one circulation, and the other is configured to shift the optical path in a second direction by one circulation,
the first direction is perpendicular to both a direction of the discharge and a direction of an optical path axis of the optical resonator, and
the second direction is the direction of the discharge.

20. A method of manufacturing an electronic device comprising:
generating a laser beam with a laser apparatus, the laser apparatus including
a laser oscillator including an optical resonator and a pair of electrodes that apply a voltage to a laser gas to cause discharge, and configured to output a first pulse laser beam,
a first optical pulse stretcher disposed in an optical path of the first pulse laser beam, configured to output a second pulse laser beam for which a pulse time width of the first pulse laser beam is extended by transmitting a part of the first pulse laser beam, making the other part circulate once, and outputting first transmitted light and first once-circulating light, and configured such that an optical path of the first transmitted light and an optical path of the first once-circulating light spatially partially overlap with a first shift amount in a first direction, and
a second optical pulse stretcher disposed in an optical path of the second pulse laser beam, configured to output a third pulse laser beam for which a pulse time width of the second pulse laser beam is extended by transmitting a part of the second pulse laser beam, making the other part circulate once, and outputting second transmitted light and second once-circulating light, and configured such that an optical path of the second transmitted light and an optical path of the second once-circulating light spatially partially overlap with a second shift amount, which is different from the first shift amount, in the first direction;
outputting the laser beam to an exposure apparatus; and
exposing a photosensitive substrate to the laser beam within the exposure apparatus to manufacture an electronic device.
